(19) United States
(12) Patent Application Publication
(10) Pub. No.: US 2023/0019866 A1
(43) Pub. Date: Jan. 19, 2023

(54) SEMICONDUCTOR DEVICE, MANUFACTURING METHOD THEREOF, AND DISPLAY PANEL

(71) Applicant: TCL CHINA STAR OPTOELECTRONICS TECHNOLOGY CO., LTD., Shenzhen, Guangdong (CN)

(72) Inventor: Guangshuo CAI, Shenzhen, Guangdong (CN)

(21) Appl. No.: 17/599,532

(22) PCT Filed: Jul. 19, 2021
(86) PCT No.: PCT/CN2021/107011

§ 371 Date: Sep. 28, 2021

(30) Foreign Application Priority Data
Apr. 29, 2021 (CN) 202110474010.9

(51) Int. Cl. H01L 27/12

(52) U.S. Cl. CPC H01L 27/1222; H01L 27/127; H01L 27/1244

(57) ABSTRACT

A semiconductor device, a manufacturing method thereof, and a display panel are provided. The semiconductor device includes a first active component. The first active component includes a first semiconductor layer and a contact layer. The contact layer includes a first doped layer, a second semiconductor layer, and a second doped layer stacked from bottom to top, so that there are at least two PN junction interfaces inside to increase a light to dark current ratio of the semiconductor device.

### FIELD OF DISCLOSURE

The present disclosure relates to the field of display technologies, in particular to a semiconductor device, a manufacturing method thereof, and a display panel.

### BACKGROUND

In terms of cost, ease of use, and accuracy, fingerprint identification has become a leading method for identity verification, replacing conventional passwords and keys. Traditional fingerprint identification optical sensors have problems such as high cost, large volume, and image distortion. Sensors based on silicon chips are favored by people because they can be made very small and cheap. However, they are prone to electrostatic breakdown and may be damaged by environmental conditions, which limits their further applications.

In comparison with silicon-based PN junction sensors, fingerprint and palmprint light sensors using amorphous silicon transistors (a-Si TFT) have advantages of high quantum efficiency, high reliability, and low cost. However, since a reflected light of the fingerprint or the palmprint in practical applications is extremely weak and fingerprint spacings is small, the sensor is required to have a small occupied area and high photo-responsiveness at the same time. Low-light sensor devices, such as fingerprint sensors, need to generate a photocurrent of more than 10⁻¹¹ A under a light intensity of 50 lx. Due to the requirement of resolution, it is also necessary to limit the area of the sensing unit within 80 um*80 um (taking 300 dpi as an example).

FIG. 1 shows transfer characteristic curves of a conventional amorphous silicon transistor under different white light intensities. In FIG. 1, the curves from bottom to top is 0 lx (indicated by dark in FIG. 1), 47.5 lx, 115 lx, and 250 lx. As shown in FIG. 1, when a negative pressure is less than −30V, the transfer characteristic curves of 0 lx, 47.5 lx, 115 lx, and 250 lx are close to each other and cannot be distinguished, thereby reducing a light to dark current ratio and reliability of the sensor. It is difficult to meet the application requirements of fingerprint sensing. Therefore, the performance of the traditional amorphous silicon transistor (a-Si TFT) is difficult to meet the application requirements of fingerprint sensing. It is prone to a Poole-Frenkel effect under high negative pressure, which reduces the light to dark current ratio of the sensor and reliability. It is difficult to meet a fast response application of low light sensing.

### SUMMARY OF DISCLOSURE

A purpose of the present disclosure is to provide a semiconductor device, a manufacturing method thereof, and a display panel, to solve existing technical problems that because amorphous silicon transistor sensors are prone to Poole-Frenkel effect under high negative pressure, which reduces a light to dark current ratio and reliability of the sensors.

In order to achieve the above purpose, the present disclosure provides a semiconductor device, including a substrate, a first gate, a gate insulating layer, a first active component, a first source, and a first drain. The first gate is disposed on the substrate. The gate insulating layer is disposed on the first gate and covers the first gate. The first active component is disposed on the gate insulating layer and corresponds to the first gate. The first active component includes a channel region and doped regions arranged on both sides of the channel region. The first source is disposed on the first active component and electrically connected to one of the doped regions of the first active component. The first drain is disposed on the first active component and electrically connected to another doped region of the first active component. The first active component includes a first semiconductor layer and a contact layer. The contact layer is disposed on the first semiconductor layer and disposed in the doped regions. The contact layer includes a first doped layer, a second semiconductor layer, and a second doped layer which are stacked in sequence from bottom to top. Specifically, the first doped layer is disposed on the first semiconductor layer. The second semiconductor layer is disposed on the first doped layer. The second doped layer is disposed on the second semiconductor layer.

Furthermore, the first semiconductor layer is an amorphous silicon layer. The first doped layer is an N-type doped amorphous silicon layer. The second semiconductor layer is an amorphous silicon layer. The second doped layer is an N-type doped amorphous silicon layer.

Furthermore, a thickness of the first doped layer ranges from 5 nm to 10 nm. A thickness of the second semiconductor layer ranges from 10 nm to 12 nm. A thickness of the second doped layer ranges from 5 nm to 10 nm.

Based on the aforementioned semiconductor device, the present disclosure also provides a manufacturing method of a semiconductor device, including steps of:

forming a first gate, wherein a metal layer is deposited on a substrate and it is patterned to form the first gate;

forming a gate insulating layer, wherein the gate insulating layer is formed on the first gate, and the gate insulating layer covers the first gate;

forming a first active component, wherein the first active component formed on the gate insulating layer and corresponds to the first gate, the first active component includes a channel region and doped regions arranged on both sides of the channel region; and

forming a first source and a first drain, wherein a metal layer is deposited on the first active component and corresponds to the doped regions, it is patterned to form the first source and the first drain, the first source and the first drain are respectively electrically connected to two of the doped regions of the first active component.

Furthermore, the step of forming the first active component includes:

forming a first semiconductor layer, wherein an amorphous layer is deposited on the gate insulating layer by chemical vapor deposition and it is patterned to form the first semiconductor layer corresponding to the first gate;

forming a first doped layer, wherein the first doped layer is formed on doped regions of the first semiconductor layer by chemical vapor deposition;

forming a second semiconductor layer, wherein the second semiconductor layer is formed on the first doped layer by chemical vapor deposition; and

forming a second doped layer, wherein the second doped layer is formed on the second semiconductor layer by chemical vapor deposition, the first doped layer, the second semiconductor layer, and the second doped layer together form a contact layer, and the first semiconductor layer and the contact layer together form the first active component.

Furthermore, the step of forming the first doped layer includes: using H₂ and SiH₄ as reaction gases, using PH₃ as a doping gas, controlling a flow ratio of PH₃ and SiH₄ to be 0.3 to 0.7, and depositing, by chemical vapor deposition, an amorphous layer on the semiconductor layer to form the first doped layer. The step of forming the second semiconductor layer includes: using H₂ and SiH₄ as reaction gases and depositing, by chemical vapor deposition, an amorphous layer on the first doped layer to form the second semiconductor layer. The step of forming the second doped layer includes: using H₂ and SiH₄ as reaction gases, using PH₃ as a doping gas, controlling a flow ratio of PH₃ and SiH₄ to 2 to 3, and depositing, by chemical vapor deposition, an amorphous layer on the second semiconductor layer to form the second doped layer.

Based on the same inventive concept, the present disclosure also provides a display panel, including a light sensor and a switching transistor. The light sensor and the switching transistor both use the aforementioned semiconductor device. Film layers of the light sensor and the switching transistor are correspondingly arranged in same layers.

Based on the same inventive concept, the present disclosure also provides a display panel, including a substrate, a light sensor, a switching transistor, a protective layer, and a wiring layer. The light sensor includes a substrate, a first gate, a gate insulating layer, a first active component, a first source, and a first drain. The first gate is disposed on the substrate. The gate insulating layer is disposed on the first gate and covers the first gate. The first active component is disposed on the gate insulating layer and corresponds to the first gate. The first active component includes a channel region and doped regions arranged on both sides of the channel region. The first source is disposed on the first active component and electrically connected to one of the doped regions of the first active component. The first drain is disposed on the first active component and electrically connected to another doped region of the first active component. The first active component includes a first semiconductor layer and a contact layer. The contact layer is disposed on the first semiconductor layer and disposed in the doped regions. The contact layer includes a first doped layer, a second semiconductor layer, and a second doped layer which are stacked in sequence from bottom to top. The first doped layer is disposed on the first semiconductor layer. The second semiconductor layer is disposed on the first doped layer. The second doped layer is disposed on the second semiconductor layer. The switching transistor includes a second gate, a second active component, a second source, and a second drain. The second gate is disposed between the substrate and the gate insulating layer. The second active component is disposed on the gate insulating layer and corresponds to the second gate. The second source is disposed on the second active component. The second drain is disposed on the second active component. The protective layer is disposed on the gate insulating layer and covers the first source, the first drain, the second source, and the second drain. The wiring layer is disposed on the protective layer. A portion of the wiring layer is electrically connected to one of the first source and the first drain through a first via hole of the protective layer, and another portion of the wiring layer is electrically connected to one of the second source and the second drain through a second via hole of the protective layer.

Furthermore, material of the first active component and the second active component includes any one of amorphous silicon, IZO, In₂O₃, IGZO, and ZnO.

Furthermore, the display panel further includes a light-shielding layer disposed on the switching transistor. A projection of the second active component on the substrate is within a projection of the light-shielding layer on the substrate.

Furthermore, the first semiconductor layer is an amorphous silicon layer. The first doped layer is an N-type doped amorphous silicon layer. The second semiconductor layer is an amorphous silicon layer. The second doped layer is an N-type doped amorphous silicon layer.

Furthermore, a thickness of the first doped layer ranges from 5 nm to 10 nm. A thickness of the second semiconductor layer ranges from 10 nm to 12 nm. A thickness of the second doped layer ranges from 5 nm to 10 nm

Furthermore, the second active component includes a third semiconductor layer and a third doped layer. The third semiconductor layer is disposed on the gate insulating layer. The third doped layer is disposed on the third semiconductor layer. Alternatively, the second active component has the same structure as the first active component, includes a first semiconductor layer and a contact layer. The contact layer is disposed on the first semiconductor layer and disposed in the doped regions. The contact layer includes a first doped layer, a second semiconductor layer, and a second doped layer which are sequentially stacked from bottom to top. Specifically, the first doped layer is disposed on the first semiconductor layer. The second semiconductor layer is disposed on the first doped layer. The second doped layer is disposed on the second semiconductor layer.

Advantages of the present disclosure are as follows. The semiconductor device, the manufacturing method thereof, and the display panel are provided. By setting the first active component to the first semiconductor layer and contact layer, the contact layer includes the first doped layer, the second semiconductor layer, and the second doped layer that are sequentially stacked from bottom to top. Thus, there are at least two PN junction interfaces inside, which increases a light to dark current ratio of the semiconductor device. The Poole-Frenkel effect of the transistor structure can be prevented. The light to dark current ratio and reliability of semiconductor device are optimized. A fingerprint/palmprint semiconductor device with high-response, small occupied area, and low-cost is provided, which achieves a goal of high response in low light.

### BRIEF DESCRIPTION OF DRAWINGS

The following describes specific implementations of the present disclosure in detail with reference to accompanying drawings, which will make technical solutions and other beneficial effects of the present disclosure clearer.

FIG. 1 shows transfer characteristic curves of a conventional amorphous silicon transistor under different white light intensities.

FIG. 2 is a schematic diagram of a display panel of a first embodiment of the present disclosure.

FIG. 3 is a schematic diagram of a semiconductor device of an embodiment of the present disclosure.

FIG. 4 shows transfer characteristic curves of the semiconductor device of the embodiment of the present disclosure under different white light intensities.

FIG. 5 is a graph showing variations of photo-response current of the semiconductor device in the embodiment of the present disclosure under different white light intensities.

FIG. 6 is an analysis diagram of an energy band principle of at least two PN junction interfaces in a contact layer of the embodiment of the present disclosure.

FIG. 7 is a schematic diagram of a display panel of a second embodiment of the present disclosure.

FIG. 8 is a flowchart of a manufacturing method of a semiconductor device of an embodiment of the present disclosure.

FIG. 9 is a flowchart of a manufacturing method of a first active component of an embodiment of the present disclosure.

FIG. 10 is a flowchart of a manufacturing method of a contact layer of an embodiment of the present disclosure.

FIG. 11 is a flowchart of a manufacturing method of a display panel of an embodiment of the present disclosure.

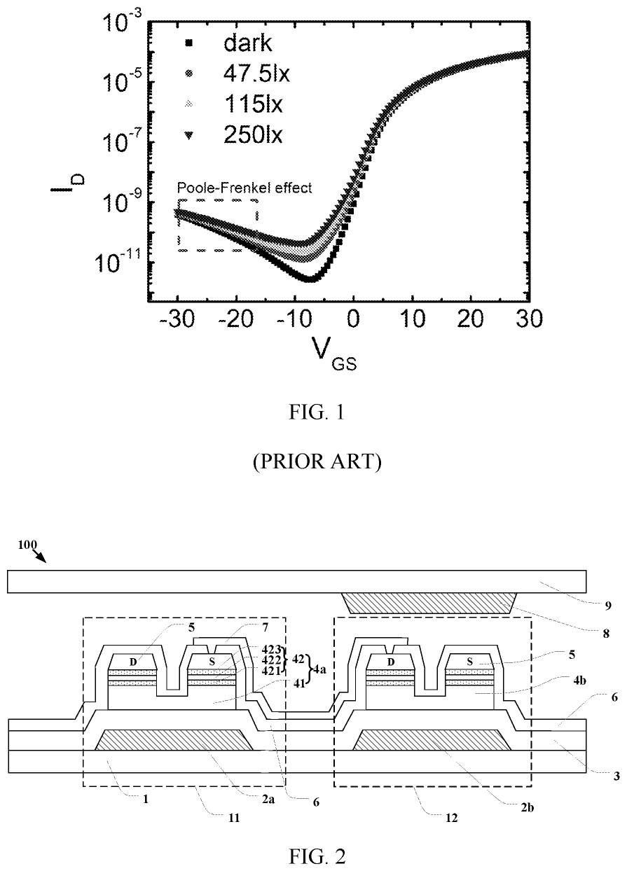

Reference numerals of elements in the drawings as follows:

substrate 1, first gate 2a, second gate layer 2b,

gate insulating layer 3, first active component 4a, second active component 4b,

source-drain layer 5, protective layer 6, wiring layer 7,

light-shielding layer 8, cover 9, semiconductor device 10,

light sensor 11, switching transistor 12, first semiconductor layer 41,

contact layer 42, third semiconductor layer 43, third doped layer 44,

display panel 100, first doped layer 421, second semiconductor layer 422,

second doped layer 423.

### DETAILED DESCRIPTION

Technical solutions in the embodiments of the present disclosure will be clearly and completely described below in conjunction with the drawings in the embodiments of the present disclosure. Apparently, the described embodiments are only a part of the embodiments of the present disclosure, rather than all the embodiments. Based on the embodiments in the present disclosure, all other embodiments obtained by those skilled in the art without creative efforts shall fall within the scope of protection of the present disclosure.

### First Embodiment

Referring to FIG. 2, a display panel 100 is provided in the first embodiment of the present disclosure. The display panel 100 includes a substrate 1, a driving circuit layer, a protective layer 6, and a wiring layer 7 which are sequentially stacked from bottom to top. The driving circuit layer includes a light sensor 11 and a switching transistor 12. Material of the substrate 1 includes at least one of glass, Al₂O₃, polyethylene naphthalate, polyethylene terephthalate (PET), and polyimide (PI). The protective layer 6 is a transparent insulating layer, and its material includes at least one of aluminum oxide, silicon nitride, silicon dioxide, aluminum nitride, and zirconium oxide. The wiring layer 7 includes at least one structure of indium tin oxide (ITO), Mo/Cu, Mo/Al, Al, MoTi/Cu, MoTi/Al, Ni/Cu, Ni/Al, Cd/Cu, Cd/Al, Ti/Cu, and Ti/Al.

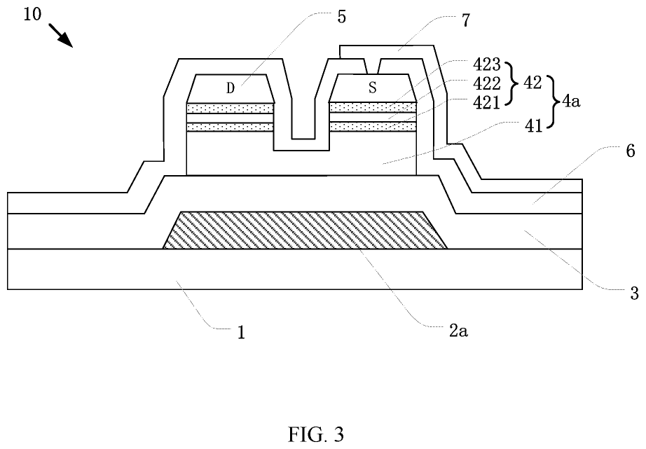

As shown in FIG. 3, the present disclosure provides a semiconductor device 10. The semiconductor device 10 can be used as the structure of the light sensor 11 or the switching transistor 12. When the semiconductor device 10 is used as the light sensor 11, it can realize a fast response to weak light.

As shown in FIG. 2, the light sensor 11 and the switching transistor 12 both use the semiconductor device 10 described above. Film layers of the light sensor 11 and the switching transistor 12 are arranged corresponding to same layers. That is, the switching transistor 12 and the semiconductor device 10 are arranged in parallel. The light sensor 11 and the switching transistor 12 form an array substrate structure arranged in an array. This can facilitate the production of the same structure in different functional areas to achieve different functions, and can simplify the production process.

Specifically, as shown in FIG. 3 and FIG. 2, the semiconductor device 10 includes a substrate 1, a first gate 2a, a gate insulating layer 3, a first active component 4a, and a source-drain layer 5. The source-drain layer 5 includes a first source S and a first drain D. The first gate 2a is disposed on the substrate 1. The first gate 2a includes at least one structure of indium tin oxide (ITO), Mo/Cu, Al/Mo, Al, MoTi/Cu, Al/MoTi, Ni/Cu, Al/Ni, Cd/Cu, Al/Cd, Ti/Cu, and Al/Ti. The gate insulating layer 3 is disposed on the substrate 1 and covers the first gate 2a. Material of the gate insulating layer 3 includes at least one of aluminum oxide, silicon nitride, silicon dioxide, aluminum nitride, and zirconium oxide. The first active component 4a is disposed on the gate insulating layer 3 and corresponding to the first gate 2a. The first active component 4a includes a channel region and doped regions arranged on both sides of the channel region. The first active component 4a includes a first semiconductor layer 41 and a contact layer 42. The first semiconductor layer 41 is disposed on the gate insulating layer 3. The contact layer 42 is disposed on the first semiconductor layer 41. The contact layer 42 includes a first doped layer 421 (NP1), a second semiconductor layer 422 (AH), and a second doped layer 423 (NP2) stacked from bottom to top, so that there are at least two PN junction interfaces inside to increase the light to dark current ratio of the semiconductor device 10. The source-drain layer 5 is disposed on the first active component 4a. The source-drain layer 5 is disposed in the doped regions and is electrically connected to the first active component 4a. The source-drain layer 5 includes at least one structure of indium tin oxide (ITO), Mo/Cu, Mo/Al, Al, MoTi/Cu, MoTi/Al, Ni/Cu, Ni/Al, Cd/Cu, Cd/Al, Ti/Cu, and Ti/Al. The first source S is disposed on the first active component 4a, and is electrically connected to one of the doped regions of the first active component 4a. The first drain D is disposed on the first active component 4a and is electrically connected to another doped region of the first active component 4a. The PN junction interfaces are contact surfaces of PN junctions of the transistor, which has a transition barrier for carriers. A sum of the transition barriers of carriers at a plurality of the PN junction interfaces is greater than the transition barriers of carriers at one PN junction interface in the prior art, which can effectively reduce leakage current and increase the light to dark current ratio of the semiconductor device 10. It is understandable that the light to dark current ratio is a ratio of a photo-response current under bright light intensity to a photo-response current under dark light intensity in the variations of the photo-response current of the semiconductor device 10 under different white light intensities.

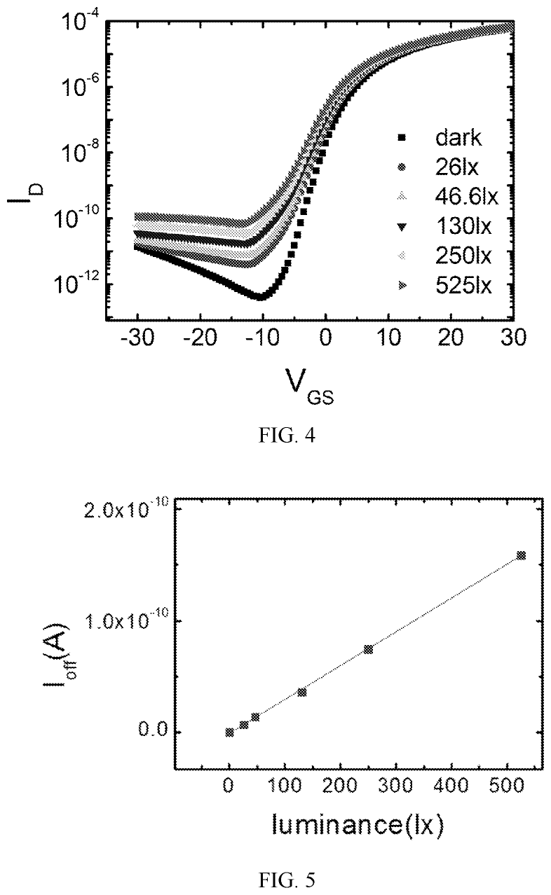

Referring to FIG. 4, which shows transfer characteristic curves of the semiconductor device 10 under different white light intensities. In FIG. 4, the curves from bottom to top is 0 lx (represented by dark in FIG. 4), 26 lx, 46.6 lx, 130 lx, 250 lx, and 525 lx. As can be seen in FIG. 4, the Poole-Frenkel effect is small, a photo-responsiveness is large, and the light to dark current ratio is increased to 120 at 250 lx.

Referring to FIG. 5, which is a graph showing variations of photo-response current of the semiconductor device 10 under different white light intensities (luminance, unit is lx). When a gate voltage Vgs=−10V and Vd=15V, the current response of the semiconductor device 10 at 50 lx reaches 1.4*10⁻¹¹ A, thereby achieving a goal of high response to weak light.

Specifically, in this embodiment, the first doped layer 421 of the contact layer 42 is disposed on the semiconductor layer 41. The second semiconductor layer 422 is disposed on the first doped layer 421. The second doped layer 423 is disposed on the second semiconductor layer 422. A first PN junction interface is formed between the first doped layer 421 and the semiconductor layer 41. A second PN junction interface is formed between the second doped layer 423 and the second semiconductor layer 422. A transition barrier of carriers at the first PN junction interface is smaller than a transition barrier of carriers at the second PN junction interface.

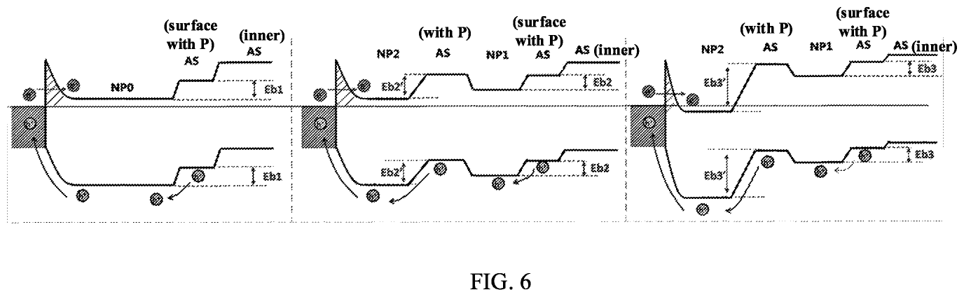

Referring to FIG. 6, which is an analysis diagram of an energy band principle of at least two PN junction interfaces in the contact layer 42. Taking the first PN junction interface and the second PN junction interface in the contact layer 42 as an example, in FIG. 6, a diagram of an energy band principle of an undoped transistor, a diagram of an energy band principle of a reference doped transistor, and a diagram of an energy band principle of the semiconductor device 10 of this embodiment are shown from left to right.

A structure of the undoped transistor is formed by disposing an undoped layer (indicated by NP0 in FIG. 6) on the first semiconductor layer (indicated by AS₍ᵢₙₙₑᵣ₎ in FIG. 6). A thickness of the undoped layer NP0 is 150 angstroms, and flow rates of PH₃ and SiH₄ are 19180 and 13900 respectively during preparation.

A structure of the reference doped transistor is formed by sequentially disposing a first reference doped layer (indicated by NP1 in FIG. 6), a second semiconductor layer (indicated by AS_{(surface with P)} in FIG. 6), and a second reference doped layer (indicated by NP2 in FIG. 6) on the first semiconductor layer (indicated by AS₍ᵢₙₙₑᵣ₎ in FIG. 6). A thickness of the first reference doped layer NP1 is 50 angstroms, and flow rates of PH₃ and SiH₄ used in the preparation are 19180 and 13900 respectively. For reference, the thickness of P on the surface of the second semiconductor layer AS is 50 angstroms. The flow rates of PH₃ and SiH₄ used in the preparation are 0 and 13900, respectively. A thickness of the second reference doped layer NP2 is 100 angstroms, and flow rates of PH₃ and SiH₄ used in the preparation are 19180 and 9500, respectively.

A structure of the semiconductor device 10 of this embodiment is formed by sequentially disposing the first doped layer 421 (indicated by NP1 in FIG. 6), the second semiconductor layer 422 (indicated by AS_{(surface with P)} in FIG. 6), and the second doped layer 423 (indicated by NP2 in FIG. 6) on the first semiconductor layer (indicated by AS₍ᵢₙₙₑᵣ₎ in FIG. 6). A thickness of the first doped layer 421 is 50 angstroms, and flow rates of PH₃ and SiH₄ are 9590 and 13900 respectively during preparation. A thickness of the second semiconductor layer 422 is 50 angstroms, and flow rates of PH₃ and SiH₄ are 0 and 13900 respectively during preparation. A thickness of the second doped layer 423 is 100 angstroms, and flow rates of PH₃ and SiH₄ are 24000 and 9500 respectively during preparation.

In FIG. 6, the reference doped transistor and the undoped transistor that are shown in order from left to right. In comparison with the undoped transistor, a number of the PN junction interfaces is increased in the reference doped transistor. In comparison with the reference doped transistor, a transition barrier value of carriers at the PN junction interfaces is increased in the semiconductor device 10 of this embodiment. The undoped transistor has only one PN junction interface, and its carrier transition barrier value is Eb1. The reference doped transistor has two PN junction interfaces, and transition barrier values of its carriers are Eb2 and Eb2′ respectively. In comparison with the undoped transistor, the reference doped transistor has more PN junction interfaces. The transition barrier of carriers is Eb2+Eb2′>Eb1, which can effectively reduce the leakage current. The semiconductor device 10 of this embodiment has two PN junction interfaces, and transition barrier values of its carriers are Eb3 and Eb3′ respectively. Eb3<Eb2, Eb3′>Eb2′, Eb3+Eb3′>Eb2+Eb2′. By adjusting a PH₃ flux, in comparison with the reference doped transistor, a doping concentration difference between NP1 and NP2 is further increased, and the leakage current can be further reduced.

Through the comparisons, it can be seen that the semiconductor device 10 of this embodiment has at least two PN junction interfaces in the contact layer to increase the light to dark current ratio of the semiconductor device. It can prevents the Poole-Frenkel effect of the transistor structure, optimize the light to dark current ratio and reliability of the semiconductor device. A fingerprint/palmprint semiconductor device with high-response, small occupied area, and low-cost is provided, which achieves the goal of high response in weak light.

In this embodiment, a thickness ratio of the first doped layer 421 to the second semiconductor layer 422 ranges from 1:3 to 1:2, and preferably is 0.35, 0.4, or 0.45. A thickness ratio of the second semiconductor layer 422 to the second doped layer 423 is 3:2 to 2:1, preferably is 1.6, 1.7, 1.8, 1.9. A thickness of the first doped layer 421 ranges from 5 to 10 nm, and preferably is 6 nm, 7 nm, 8 nm, or 9 nm. A thickness of the second semiconductor layer 422 ranges from 10 to 12 nm, and preferably is 11 nm. A thickness of the second doped layer 423 ranges from 5 to 10 nm, and preferably is 6 nm, 7 nm, 8 nm, or 9 nm. More preferably, the thickness of the first doped layer 421 is 5 nm, the thickness of the second semiconductor layer 422 is 15 nm, and the thickness of the second doped layer 423 is 10 nm.

In this embodiment, material of the semiconductor layer 41 includes amorphous silicon. The first doped layer 421 is made of amorphous silicon by chemical vapor deposition, using H₂ and SiH₄ as reaction gases, using PH3 as doping gas, and controlling a flow ratio of PH₃ and SiH₄ to be 0.3 to 0.7. The second semiconductor layer 422 is made of amorphous silicon by chemical vapor deposition, and using H₂ and SiH₄ as reaction gases. The second doped layer 423 is made of amorphous silicon by chemical vapor deposition, using H₂ and SiH₄ as reaction gases, using PH₃ as doping gas, and controlling a flow ratio of PH₃ and SiH₄ to be 2 to 3.

In this embodiment, the wiring layer 7 is disposed on the protective layer 6 and is electrically connected to the source-drain layer 5. Specifically, the protective layer 6 is provided with a via hole corresponding to the source-drain layer 5. The wiring layer 7 is electrically connected to the source-drain layer 5 through the via hole.

In this embodiment, a light-shielding layer 8 is disposed above the switching transistor 12. The light-shielding layer 8 is configured to block light from entering the channel region of the switching transistor 12 to avoid the influence of light on the channel region of the switching transistor 12. Material of the light-shielding layer 8 includes, but is not limited to, metal, metal oxide, black matrix resin, and other organic materials. The light-shielding layer 8 can be disposed on the display panel 100, can also be disposed in a color filter layer, or can be disposed on a cover 9 above the display panel 100. Specifically, the cover 9 is disposed above the switching transistor 12. The light-shielding layer 8 is disposed on a bottom surface of the cover 9 and above the switching transistor 12.

### Second Embodiment

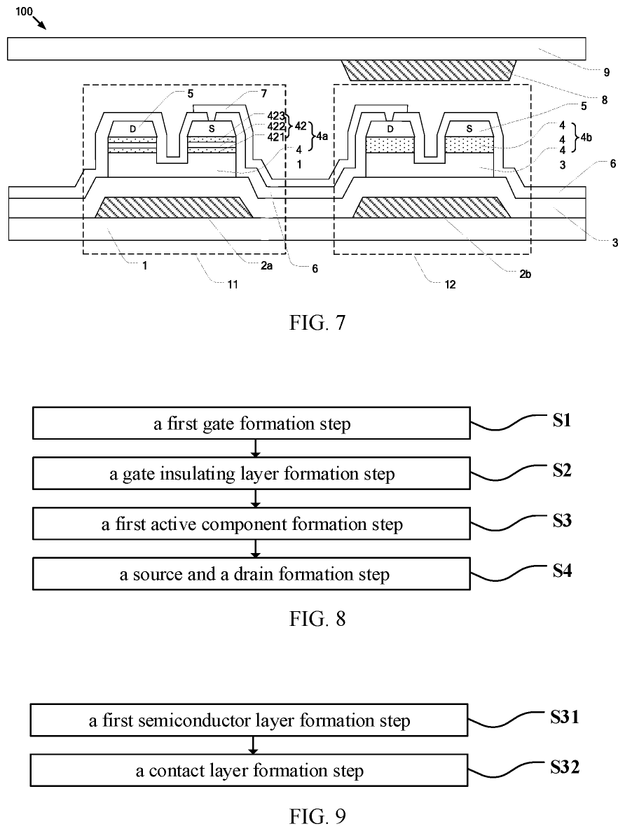

As shown in FIG. 7, the second embodiment includes most of the technical features of the first embodiment, and a difference is that in the second embodiment, only the light sensor 11 adopts the structure of the semiconductor device 10 described above, and the switching transistor 12 corresponds to the light sensor 11. This can make the light sensor 11 and the switching transistor 12 slightly different. There is no need to arrange the light-shielding layer 8 above the switching transistor 12 to prevent light from entering the channel region of the switching transistor 12.

As shown in FIG. 7, the switching transistor 12 includes a second gate 2b, a second active component 4b, and a second source S and a second drain D of the source-drain layer 5. The second gate 2b and the first gate 2a are arranged in the same layer at intervals, and are arranged between the substrate 1 and the gate insulating layer 3. That is, the gate insulating layer 3 is disposed on the second gate 2b and covers the second gate 2b. The second active component 4b is disposed on the gate insulating layer and corresponds to the second gate 2b. The second active component 4b includes a channel region and doped regions arranged on both sides of the channel region. The second source S is disposed on the second active component 4b, and is electrically connected to one of the doped regions of the second active component 4b. The second drain D is disposed on the second active component 4b, and is electrically connected to another doped region of the second active component 4b.

Similarly, in this embodiment, the display panel 100 includes the protective layer 6 and the wiring layer 7. The protective layer 6 is disposed on the gate insulating layer 3 and covers the first source S, the first drain D, the second source S, and the second drain D. The wiring layer 7 is disposed on the protective layer 6. A portion of the wiring layer 7 is electrically connected to one of the first source S and the first drain D through a first via hole of the protective layer 6. The other portion of the wiring layer 7 is electrically connected to one of the second source S and the second drain D through a second via hole of the protective layer 6.

The display panel 100 also includes a light-shielding layer 8. The light-shielding layer 8 is disposed above the switching transistor 12. A projection of the second active component 4b on the substrate 1 is within a projection of the light-shielding layer 8 on the substrate 1.

The material and the structure of the second active component 4b of the switching transistor 12 in this embodiment are different from that of the first active component 4a of the light sensor 11. The material of the first active component 4a and the second active component 4b includes at least one of amorphous silicon, IZO, In₂O₃, IGZO, ZnO, and other oxide semiconductors.

If the structure of the second active component 4b is the same as the structure of the first active component 4a, refer to FIG. 2. It the structure of the second active component 4b is different from the structure of the first active component 4a, as shown in FIG. 7, the second active component 4b includes a third semiconductor layer 43 and a third doped layer 44. The third semiconductor layer 43 is disposed on the gate insulating layer 3, and is arranged on the same layer as the first semiconductor layer 41. They are preferably formed simultaneously. The third doped layer 44 is disposed on the third semiconductor layer 43. Preferably, the third doped layer 44 is formed by doping an upper surface of the third semiconductor layer 43.

Referring to FIG. 8, based on the aforementioned semiconductor device 10, the present disclosure also provides a manufacturing method of the semiconductor device 10, which includes the following steps S1 to S4.

S1, a first gate formation step. A metal layer is deposited on a substrate 1, and it is patterned to form a first gate 2a. Preferably, the first gate 2a is formed on the substrate 1. Material of the substrate 1 includes at least one of glass, Al₂O₃, polyethylene naphthalate, polyethylene terephthalate (PET), and polyimide (PI). The first gate 2a includes at least one structure of indium tin oxide (ITO), Mo/Cu, Al/Mo, Al, MoTi/Cu, Al/MoTi, Ni/Cu, Al/Ni, Cd/Cu, Al/Cd, Ti/Cu, and Al/Ti.

S2, a gate insulating layer formation step. An insulating layer covering the first gate 2a is deposited on the substrate 1, and it is patterned to form a gate insulating layer 3. Material of the gate insulating layer 3 includes at least one of aluminum oxide, silicon nitride, silicon dioxide, aluminum nitride, and zirconium oxide. That is, the gate insulating layer 3 is disposed on the first gate 2a to cover the first gate 2a.

S3, a first active component formation step. A first active component 4a is formed on the gate insulating layer 3 corresponding to the first gate 2a. The first active component 4a includes a channel region and doped regions arranged on both sides of the channel region. Specifically, an amorphous layer is deposited on the gate insulating layer 3 by chemical vapor deposition to form the first semiconductor layer 41. The first semiconductor layer 41 is doped to form the channel region and the doped regions arranged on both sides of the channel region. A first doped layer 421, a second semiconductor layer 422, and a second doped layer 423 are sequentially formed on the first semiconductor layer 41 from bottom to top to form a contact layer 42, and the first semiconductor layer 41 and the contact layer 42 together form the first active component 4a.

Referring to FIG. 9, the formation of the first active component 4a specifically includes following steps:

S31, a first semiconductor layer formation step. An amorphous layer is deposited on the gate insulating layer 3 by chemical vapor deposition to form the first semiconductor layer 41. The first semiconductor layer 41 is doped to form the channel region and the doped regions arranged on both sides of the channel region.

S32, a contact layer formation step. The first doped layer 421, the second semiconductor layer 422, and the second doped layer 423 are sequentially formed on the first semiconductor layer 41 from bottom to top to form the contact layer 42. There are at least two PN junction interfaces in the contact layer 42 to increase the light to dark current ratio of the semiconductor device 10.

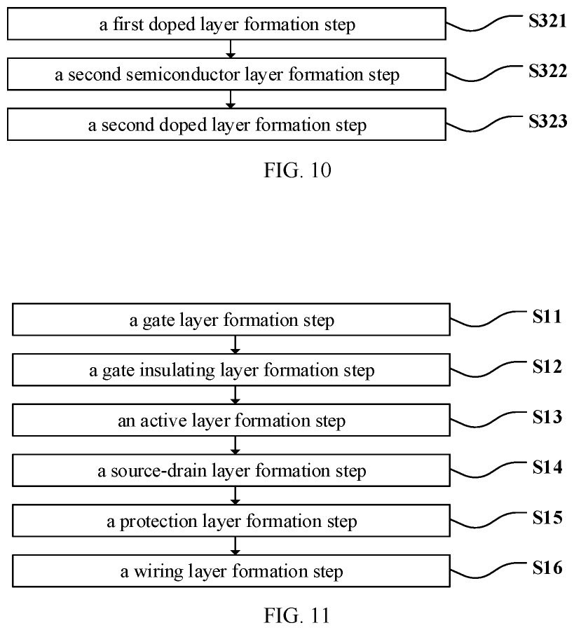

In this embodiment, referring to FIG. 10, the formation of the contact layer 42 specifically includes following steps:

S321, a first doped layer formation step. An amorphous layer is deposited on the semiconductor layer 41 by using H₂ and SiH₄ as reaction gas, using PH₃ as doping gas, controlling a flow ratio of PH₃ and SiH₄ to be 0.3 to 0.7, preferably the flow ratio of PH₃ and SiH₄ is 0.69, using a chemical vapor deposition method, to form the first doped layer 421 (NP1).

S322, a second semiconductor layer formation step. An amorphous layer is deposited on the first doped layer 421 by using the chemical vapor deposition method to form the second semiconductor layer 422 (AH).

S323, a second doped layer formation step. An amorphous layer is deposited on the second semiconductor layer 422 (AH) by using H₂ and SiH₄ as reaction gas, using PH₃ as doping gas, controlling a flow ratio of PH₃ and SiH₄ to be 2 to 3, preferably the flow ratio of PH₃ and SiH₄ is 2.5, using the chemical vapor deposition method, to form the second doped layer 423 (NP2).

A first PN junction interface is formed between the first doped layer 421 and the semiconductor layer 41. A second PN junction interface is formed between the second doped layer 423 and the second semiconductor layer 422. The transition barrier of carriers at the first PN junction interface is smaller than the transition barrier of carriers at the second PN junction interface. The semiconductor device 10 of this embodiment can reduce leakage current. The analysis diagrams of energy band principle are shown in FIG. 6. The specific comparative analysis content is detailed in the foregoing, and will not be repeated here.

In this embodiment, in the contact layer 42 formation step, a thickness ratio of the first doped layer 421 to the second semiconductor layer 422 ranges from 1:3 to 1:2, a thickness ratio of the second semiconductor layer 422 to the second doped layer 423 is 3:2 to 2:1, and a thickness ratio of the second semiconductor layer 422 to the second doped layer 423 is 3:2 to 2:1. A thickness of the first doped layer 421 ranges from 5 to 10 nm, a thickness of the second semiconductor layer 422 ranges from 10 to 12 nm, and a thickness of the second doped layer 423 ranges from 5 to 10 nm. Preferably, the thickness of the first doped layer 421 is 5 nm, the thickness of the second semiconductor layer 422 is 15 nm, and the thickness of the second doped layer 423 is 10 nm.

S4, a first source and a first drain formation step. A metal layer is deposited in the doped regions on the first active component 4a, and it is patterned to form a source-drain layer 5. The source-drain layer 5 includes a first source S and a first drain D. The first source S and the first drain D are respectively electrically connected to the first active component 4a and the corresponding portions of the two doped regions. The source-drain layer 5 includes at least one structure of indium tin oxide (ITO), Mo/Cu, Mo/Al, Al, MoTi/Cu, MoTi/Al, Ni/Cu, Ni/Al, Cd/Cu, Cd/Al, Ti/Cu, and Ti/Al.

Referring to FIG. 11, based on the display panel 100 described above, the present disclosure also provides a manufacturing method of the display panel 100, which includes the following steps S11 to S16.

S11, a gate layer formation step. A metal layer is deposited on a substrate 1, and it is patterned to form a first gate 2a and a second gate 2b. Material of the substrate 1 includes at least one of glass, Al₂O₃, polyethylene naphthalate, polyethylene terephthalate (PET), and polyimide (PI). The first gate 2a includes at least one structure of indium tin oxide (ITO), Mo/Cu, Al/Mo, Al, MoTi/Cu, Al/MoTi, Ni/Cu, Al/Ni, Cd/Cu, Al/Cd, Ti/Cu, and Al/Ti.

S12, a gate insulating layer formation step. An insulating layer covering the first gate 2a is deposited on the substrate 1, and it is patterned to form a gate insulating layer 3. Material of the gate insulating layer 3 includes at least one of aluminum oxide, silicon nitride, silicon dioxide, aluminum nitride, and zirconium oxide. That is, the gate insulating layer 3 is formed on the first gate 2a to cover the first gate 2a.

S13, an active layer formation step. A first active component 4a is formed on the gate insulating layer 3 corresponding to the first gate 2a. The first active component 4a includes a channel region and doped regions arranged on both sides of the channel region. A second active component 4b is formed on the gate insulating layer 3 corresponding to the second gate 2b. The first active component 4a and the second active component 4b together form the active layer.

S14, a source-drain layer formation step. A metal layer is deposited on the active layer in the doped regions, and it is patterned to form a source-drain layer 5. The source-drain layer 5 includes a first source, a second source, a first drain, and a second drain that are correspondingly electrically connected to the doped regions. The source-drain layer 5 includes at least one structure of indium tin oxide (ITO), Mo/Cu, Mo/Al, Al, MoTi/Cu, MoTi/Al, Ni/Cu, Ni/Al, Cd/Cu, Cd/Al, Ti/Cu, and Ti/Al.

S15, a protective layer formation step. A protective layer 6 is formed on the gate insulating layer 3 by depositing a transparent insulating layer covering the source-drain layer 5. Material of the protective layer 6 includes at least one of aluminum oxide, silicon nitride, silicon dioxide, aluminum nitride, and zirconium oxide.

S16, a wiring layer formation step. A metal layer electrically connected to the source-drain layer 5 is deposited on the protective layer 6, and it is patterned to form a wiring layer 7. Specifically, the protective layer 6 is provided with a via hole corresponding to the source of the source-drain layer 5. The wiring layer 7 is electrically connected to the source of the source-drain layer 5 through the via hole. The wiring layer 7 includes at least one structure of indium tin oxide (ITO), Mo/Cu, Mo/Al, Al, MoTi/Cu, MoTi/Al, Ni/Cu, Ni/Al, Cd/Cu, Cd/Al, Ti/Cu, and Ti/Al.

Referring to FIG. 4, which shows transfer characteristic curves of the semiconductor device 10 under different white light intensities. In FIG. 4, the curves from bottom to top is 0 lx (represented by dark in FIG. 4), 26 lx, 46.6 lx, 130 lx, 250 lx, and 525 lx. As can be seen in FIG. 4, the Poole-Frenkel effect is small, a photo-responsiveness is large, and the light to dark current ratio is increased to 120 at 250 lx.

Referring to FIG. 5, which is a graph showing variations of photo-response current of the semiconductor device 10 under different white light intensities. When a gate voltage Vgs=−10V and Vd=15V, the current response of the semiconductor device 10 at 50 lx reaches 1.4*10⁻¹¹ A, thereby achieving a goal of high response to weak light.

Advantages of the present disclosure are as follows. The semiconductor device, the manufacturing method thereof, and the display panel are provided. By setting the first active component to the first semiconductor layer and contact layer, the contact layer includes the first doped layer, the second semiconductor layer, and the second doped layer that are sequentially stacked from bottom to top. A fingerprint/palmprint semiconductor device with high-response, small occupied area, and low-cost is provided, which achieves a goal of high response in low light. The specific principle is that by decomposing a PN junction interface with a high energy barrier value into a plurality of PN junction interfaces with a low energy barrier value, each PN junction interface with the low energy barrier value can realize the indentification accuracy of weak light. Moreover, the PN junction interfaces can increase the light to dark current ratio of the semiconductor device as a whole. The Poole-Frenkel effect of the transistor structure can be prevented. The light to dark current ratio and reliability of semiconductor device are optimized. A fingerprint/palmprint semiconductor device with high-response, small occupied area, and low-cost is provided, which achieves a goal of high response in low light.

In the foregoing embodiments, the description of each embodiment has its own focus. For a part that is not described in detail in the embodiment, reference may be made to related descriptions of other embodiments.

The semiconductor device, the manufacturing method thereof, and the display panel of the present disclosure are described in detail above. In this specification, specific examples are used to illustrate the principle and implementations of the present disclosure. The description of the above embodiment is only used to help understand the technical solutions of the present disclosure and its core idea. Those of ordinary skill in the art should understand that they can still modify the technical solutions described in the foregoing embodiments, or equivalently replace some of the technical features. However, these modifications or replacements do not cause the essence of the corresponding technical solutions to deviate from the scope of the technical solutions of the embodiments of the present disclosure.

What is claimed is:

1. A semiconductor device, comprising:
a substrate;
a first gate disposed on the substrate;
a gate insulating layer disposed on the first gate and covering the first gate;
a first active component disposed on the gate insulating layer and corresponding to the first gate, wherein the first active component comprises a channel region and doped regions arranged on both sides of the channel region;
a first source disposed on the first active component and electrically connected to one of the doped regions of the first active component; and
a first drain disposed on the first active component and electrically connected to another doped region of the first active component;
wherein the first active component comprises:
a first semiconductor layer; and
a contact layer disposed on the first semiconductor layer and disposed in the doped regions;
wherein the contact layer comprises:
a first doped layer disposed on the first semiconductor layer;
a second semiconductor layer disposed on the first doped layer; and
a second doped layer disposed on the second semiconductor layer.

2. The semiconductor device according to claim 1, wherein the first semiconductor layer is an amorphous silicon layer.

3. The semiconductor device according to claim 1, wherein the first doped layer is an N-type doped amorphous silicon layer.

4. The semiconductor device according to claim 1, wherein the second semiconductor layer is an amorphous silicon layer.

5. The semiconductor device according to claim 1, wherein the second doped layer is an N-type doped amorphous silicon layer.

6. The semiconductor device according to claim 1, wherein a thickness of the first doped layer ranges from 5 nm to 10 nm.

7. The semiconductor device according to claim 1, wherein a thickness of the second semiconductor layer ranges from 10 nm to 12 nm.

8. The semiconductor device according to claim 1, wherein a thickness of the second doped layer ranges from 5 nm to 10 nm.

9. A manufacturing method of a semiconductor device, comprising steps of:
forming a first gate, wherein a metal layer is deposited on a substrate and it is patterned to form the first gate;
forming a gate insulating layer, wherein the gate insulating layer is formed on the first gate, and the gate insulating layer covers the first gate;
forming a first active component, wherein the first active component formed on the gate insulating layer and corresponds to the first gate, the first active component comprises a channel region and doped regions arranged on both sides of the channel region; and
forming a first source and a first drain, wherein a metal layer is deposited on the first active component and corresponds to the doped regions, it is patterned to form the first source and the first drain, the first source and the first drain are respectively electrically connected to two of the doped regions of the first active component.

10. The manufacturing method of the semiconductor device according to claim 9, wherein the step of forming the first active component comprises:
forming a first semiconductor layer, wherein an amorphous layer is deposited on the gate insulating layer by chemical vapor deposition and it is patterned to form the first semiconductor layer corresponding to the first gate;
forming a first doped layer, wherein the first doped layer is formed on doped regions of the first semiconductor layer by chemical vapor deposition;
forming a second semiconductor layer, wherein the second semiconductor layer is formed on the first doped layer by chemical vapor deposition; and
forming a second doped layer, wherein the second doped layer is formed on the second semiconductor layer by chemical vapor deposition, the first doped layer, the second semiconductor layer, and the second doped layer together form a contact layer, and the first semiconductor layer and the contact layer together form the first active component.

11. The manufacturing method of the semiconductor device according to claim 10, wherein the step of forming the first doped layer comprises: using H₂ and SiH₄ as reaction gases, using PH₃ as a doping gas, controlling a flow ratio of PH₃ and SiH₄ to be 0.3 to 0.7, and depositing an amorphous layer on the semiconductor layer to form the first doped layer;
the step of forming the second semiconductor layer comprises: using H₂ and SiH₄ as reaction gases and depositing an amorphous layer on the first doped layer to form the second semiconductor layer; and
the step of forming the second doped layer comprises: using H₂ and SiH₄ as reaction gases, using PH₃ as a doping gas, controlling a flow ratio of PH₃ and SiH₄ to 2 to 3, and depositing an amorphous layer on the second semiconductor layer to form the second doped layer.

12. A display panel, comprising:
a substrate;
a light sensor comprising:
a first gate disposed on the substrate;
a gate insulating layer disposed on the first gate and covering the first gate;
a first active component disposed on the gate insulating layer and corresponding to the first gate, wherein the first active component comprises a channel region and doped regions arranged on both sides of the channel region;
a first source disposed on the first active component and electrically connected to one of the doped regions of the first active component; and
a first drain disposed on the first active component and electrically connected to another doped region of the first active component;
wherein the first active component comprises:
a first semiconductor layer; and
a contact layer disposed on the first semiconductor layer and disposed in the doped regions;
wherein the contact layer comprises:
a first doped layer disposed on the first semiconductor layer;
a second semiconductor layer disposed on the first doped layer; and
a second doped layer disposed on the second semiconductor layer;
a switching transistor comprising:
a second gate disposed between the substrate and the gate insulating layer;
a second active component disposed on the gate insulating layer and corresponding to the second gate;
a second source disposed on the second active component;
a second drain disposed on the second active component;
a protective layer disposed on the gate insulating layer and covering the first source, the first drain, the second source, and the second drain; and
a wiring layer disposed on the protective layer, wherein a portion of the wiring layer is electrically connected to one of the first source and the first drain through a first via hole of the protective layer, and another portion of the wiring layer is electrically connected to one of the second source and the second drain through a second via hole of the protective layer.

13. The display panel according to claim 12, wherein material of the first active component and the second active component comprises any one of amorphous silicon, IZO, In₂O₃, IGZO, and ZnO.

14. The display panel according to claim 12, further comprising: a light-shielding layer disposed on the switching transistor, wherein a projection of the second active component on the substrate is within a projection of the light-shielding layer on the substrate.

15. The display panel according to claim 12, wherein the first semiconductor layer is an amorphous silicon layer; and
the first doped layer is an N-type doped amorphous silicon layer.

16. The display panel according to claim 12, wherein the second semiconductor layer is an amorphous silicon layer; and
the second doped layer is an N-type doped amorphous silicon layer.

17. The display panel according to claim 12, wherein a thickness of the first doped layer ranges from 5 nm to 10 nm, and a thickness of the second doped layer ranges from 5 nm to 10 nm.

18. The display panel according to claim 12, wherein a thickness of the second semiconductor layer ranges from 10 nm to 12 nm.

19. The display panel according to claim 12, wherein the second active component comprises:
a third semiconductor layer disposed on the gate insulating layer; and
a third doped layer disposed on the third semiconductor layer.

20. The display panel according to claim 12, wherein the second active component comprises:
a first semiconductor layer;
a contact layer disposed on the first semiconductor layer and disposed in the doped regions, wherein the contact layer comprises:
a first doped layer disposed on the first semiconductor layer;
a second semiconductor layer disposed on the first doped layer; and
a second doped layer disposed on the second semiconductor layer.
